(19) United States
(12) Patent Application Publication
(10) Pub. No.: US 2009/0086360 A1
(43) Pub. Date: Apr. 2, 2009

(54) Low Complexity Servo Demodulation Algorithm for Probe Storage

(75) Inventors: Qiang Ling, Pittsburgh, PA (US); Mehmet Fatih Erden, Pittsburgh, PA (US)

Correspondence Address: SEAGATE TECHNOLOGY LLC C/O WESTMAN;CHAMPLIN & KELLY, P.A., SUITE 1400, 900 SECOND AVENUE SOUTH, MINNEAPOLIS, MN, 55402, US

(73) Assignee: Seagate Technology LLC, Scotts Valley, CA (US)

(21) Appl. No.: 11/866,219

(22) Filed: Oct. 2, 2007

(51) Int. Cl. H03M 1/12; G11B 21/02; H03M 3/02

(52) U.S. Cl. 360/75; 341/143; 341/155

(57) ABSTRACT

A method of calculating a position error signal is provided. The method includes receiving an analog signal from a data channel and converting the analog signal to a one bit wide digital signal. The analog signal is converted to a digital signal at an oversampled frequency. The position error signal is then calculated by summing correlated oversampled digital signals.

### FIELD OF THE DISCLOSURE

The present disclosure relates generally to data channels, and more particularly but not by limitation to servo demodulation of data received in a data communication channel.

### BACKGROUND

In data storage systems, digital data are written to and read from data storage surfaces. One well-known type of data storage system is a disk drive, which reads and writes information along concentric tracks formed on disks. Another type of data storage system is known as a probe storage system, which reads and writes information from and to a ferroelectric media. Probe storage systems have a greatly increased density for data storage (currently up to 1 Tb/in²). In order to meet high data rate requirements, an array of probe tips are used to read and write data from and to the ferroelectric medium simultaneously. Although this approach is cost efficient, such designs result in increased power consumption. As power consumption is a design constraint that can limit the capacity and speed of a probe storage system, it is desirable to minimize the amount of power consumed by probe storage system circuitry.

Thus, there is a need for probe data storage systems and methods that have circuitry designed with reduced power requirements to allow for improved capacity within the data storage systems.

### SUMMARY

The present embodiments relate to data storage systems that include power efficient analog to digital converter designs for probe storage systems, which address the above-mentioned need.

In one particular aspect, a method of calculating a position error signal is disclosed. The method includes receiving an analog signal from a data channel and converting the analog signal to a one bit wide digital signal at an oversampled frequency. The position error signal is then calculated by summing correlated oversampled digital signals.

In another aspect, a system for calculating a position error signal is discussed. The system includes a data channel configured to read an analog signal and a sigma delta modulator in communication with the data channel. The sigma delta modulator is configured to convert the analog signal to a digital signal at an oversampled rate. The system also includes a servo demodulator in communication with the sigma delta modulator for calculating the position error signal from the oversampled digital signal.

In yet another aspect of the invention, a method of determining an estimated data head position is discussed. The method includes converting an analog signal to a one bit wide digital signal by sampling the analog signal at an oversampled frequency. A position error signal is calculated by summing a plurality of digital signals at the oversampled frequency and an estimated data head position is determined based on the position error signal.

These and other features and benefits that may characterize embodiments of the present disclosure will be apparent upon reading the following detailed description and review of the associated drawings.

### BRIEF DESCRIPTION OF THE DRAWINGS

FIG. 1 illustrates a data storage system having a ferroelectric storage media that is scanned by an array of probe tips.

FIG. 2 is a schematic block diagram of an analog to digital converter with a sigma delta modulator and a decimation filter.

FIG. 3 is a schematic block diagram of a servo demodulation system incorporating the analog to digital converter of FIG. 2.

FIG. 4 is a schematic block diagram of a servo demodulation system without a decimation filter according to one aspect of the invention.

FIG. 5 is a flow chart illustrating a method of handling information read from a servo data track according to one aspect of the invention.

FIG. 6 is a block diagram of a read channel suitable for use with the servo demodulation system of FIG. 4.

FIG. 7 is a block diagram illustrating a model servo demodulation system incorporating an ideal analog to digital converter.

### DETAILED DESCRIPTION OF ILLUSTRATIVE EMBODIMENTS

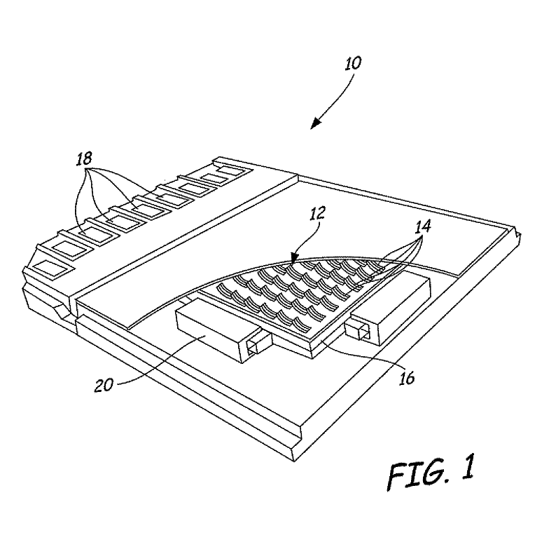

FIG. 1 illustrates an exemplary ferroelectric data storage device 10 in which one or more embodiments of the disclosure are useful. The data storage device 10 comprises a ferroelectric storage medium 16 with a scannable surface 12. An array of probes 14 contact the scannable surface 12 and communicate data to and from the scannable surface 12. Microactuators such as microactuator 20 provide relative scanning motion between the scannable surface 12 and the probes 14. Electrical contacts 18 provide connections between the device 10 and a host computer system (not shown). The connections between the device 10 and the host computer system include data communication channels, which, among other things, convert signals provided by either the host computer system or the array of probes into signals that the other of the host computer system or the array of probes can use.

The approach of employing probe storage using an array of probes to interact with a storage medium, although cost efficient for large amounts of data, results in increased power consumption in the data communication channel associated with each of the probes. It is preferable to provide a data communication channel that is power efficient, and this is especially true with respect to the analog circuitry that conditions the signal read by the read head. One of the most power hungry devices in the data communication channel is an analog-to-digital converter (ADC), which converts the analog data read by the probe into a digital signal suitable for use by, for example, a host computer. For the purposes of this application, the ADC is considered to be part of the analog portion of the channel.

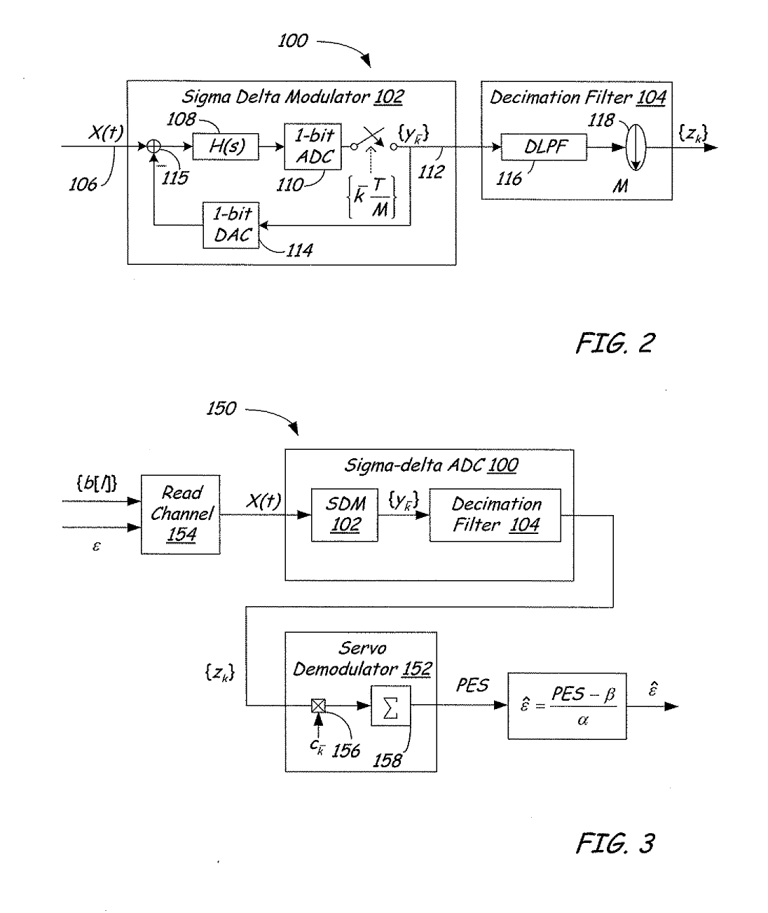

FIG. 2 illustrates a sigma-delta ADC 100 suitable for use in a probe storage application. The sigma-delta ADC 100 includes a sigma-delta modulator (SDM) 102 and a decimation filter 104. The SDM 102 is configured to receive an input analog signal 106, also represented by x(t). The input analog signal 106 to the SDM 102 is provided to an analog filter 108 with a filtering characteristic described by H(s). An output from the analog filter 108 is then provided as an input to a one bit ADC 110, which then converts the analog signal into a digital output signal 112, described as {y _{k̅}}, which is a one bit wide signal. The digital output signal 112 is illustratively provided by triggering the single-bit ADC with a clock having a frequency of M fₛ HZ, where M is an oversampling rate and fₛ is a baud rate. If the channel bit size is T, fₛ is defined as

$${f}_{e} = \frac{1}{T} .$$

To reduce the effect of quantization noise, {y _{k̅}} is fed back to the input analog signal 1061 through an adder 115 after being converted back to an analog signal via a 1-bit DAC 114. The H(s) function of the analog filter 108 is illustratively well designed so that the quantization noise in {y _{k̅}} is shaped out of the signal band. As an example, when the analog input signal 106 is band-limited at low frequency, the quantization noise in {y _{k̅}} is shaped to the high frequency range by choosing H(s) as a low-pass filter.

The decimation filter 104 provides a conversion of {y _{k̅}}, a 1-bit resolution digital signal into a high-resolution signal. The decimation filter 104 is illustratively realized for the above discussion by including a digital low-pass filter (DLPF) 116 followed by a downsampler 118, which down samples the signal at a rate of M. The output form the decimation filter 104 is represented as {zₖ}. The decimation filter 104 is illustratively implemented using finite impulse response (FIR) filters having up to several hundred taps to achieve good performance. Such a configuration requires a high computational complexity.

The sigma-delta ADC 100 is illustratively shown in a servo demodulation system 150 in FIG. 3. Because, as is discussed above, the areal densities employed in probe storage applications is so high, it is important for probe tips to be accurately positioned over narrow data tracks. One way to achieve the expected position accuracy is to employ high precision cross-track head position measurement. The servo demodulation system 150 includes a servo demodulator 152, which is configured to receive an output signal {zₖ} from the sigma delta ADC 100. Data storage device 10 illustrated in FIG. 1 often includes portions (not shown) called servo sectors that include pre-written bit sequences (that is, prior to first use in an application). A readback signal from the servo sectors is used to estimate the cross-track head position. Position estimation generated by the servo demodulator is then used by a servo controller (not shown) to control the position of the probe 14 relative to the scannable surface 12 of the data storage device 10. Because of the real time requirements of the servo controller, it is advantageous for the servo demodulator 152 to be as simple as possible.

The servo demodulation system 150 also includes a read channel 154, which receives a signal ε, which denotes the cross-track position of a given probe head. The channel 154 also illustratively receives an input {b[l]}, which is a sequence of servo bits pre-written into servo sectors, as discussed above. The output of read channel 154, readback signal x(t), is affected by ε, so ε can then be estimated from x(t). The readback signal x(t) is then provided to the sigma-delta ADC 100. The SDM 102 generates an oversampled sequence {y _{k̅}}, with a 1-bit resolution. The decimation filter 104 then is used to process {y _{k̅}} to produce an output sequence {zₖ} having a sufficient resolution and being transmitted at the baud rate to the servo demodulator 152. The output sequence {zₖ} is then illustratively provided to a multiplier 156, which multiplies {zₖ} by correlation coefficient sequence cₖ, which is illustratively ±1 so as to maintain low computational complexity. That is, the multiplication of zₖ*cₖ can be achieved by flipping the sign bit of zₖ. The product sequence {zₖ*cₖ} is then provided to an adder 158 to be summed together to generate a position error signal, PES. The PES is described as

PES=αε+β+n

where α and β are system parameters and n is noise. Thus, ε can be estimated as

$$\hat{ɛ} = \frac{PES - β}{α} .$$

Thus, the position estimation \hat{ε} is shown to be derived from the PES. For a given computation power, the computational complexity of PES is proportional to the latency to achieve the PES and the position estimation \hat{ε}. A long latency to obtain \hat{ε} may significantly degrade control performance. One factor that affects the computational complexity of the position estimation \hat{ε} include the decimation filter because of potentially hundreds of taps. Thus, it can be seen that the decimation filter is a potential bottleneck that prevents reduction of the computation complexity of the PES.

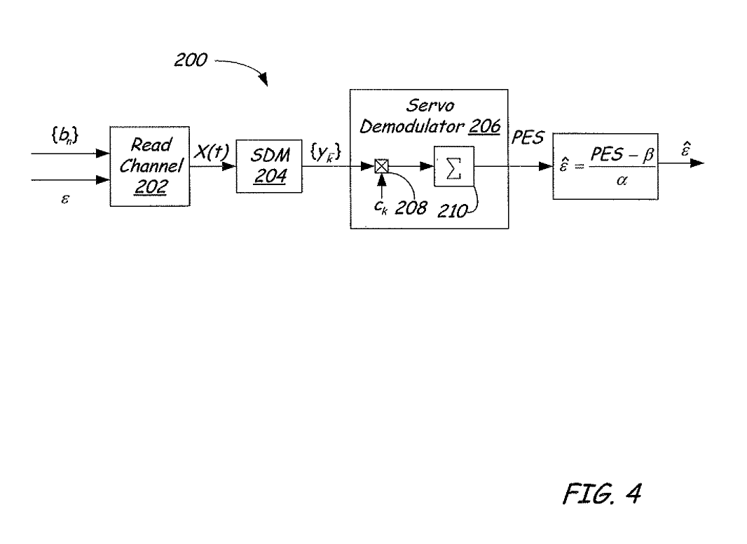

FIG. 4 illustrates a servo demodulation system 200 having a reduced complexity according to one aspect of the present invention. Servo demodulation system 200 includes a channel 202, which receives the cross-track position ε and servo bits {bₙ}. The channel 202 provides a signal x(t) to a SDM 204. The output {y _{k̅}} is illustratively provided directly to a servo demodulator 206, without first passing through a decimation filter such as in the servo demodulation system 150 discussed above. Thus, an oversampled signal is provided to the servo demodulator 204. The servo demodulator 206 includes a multiplier 208, which multiplies the input {y _{k̅}} by correlation parameter c _{k̅}. The correlation parameter c _{k̅}, unlike the correlation parameter cₖ discussed above, does not have a 1-bit resolution, but instead is described by B+1 bits. The output from multiplier 208 is provided to an adder 210, which adds the results to provide a PES signal. From the PES signal, an estimator provides a position estimation, \hat{ε}.

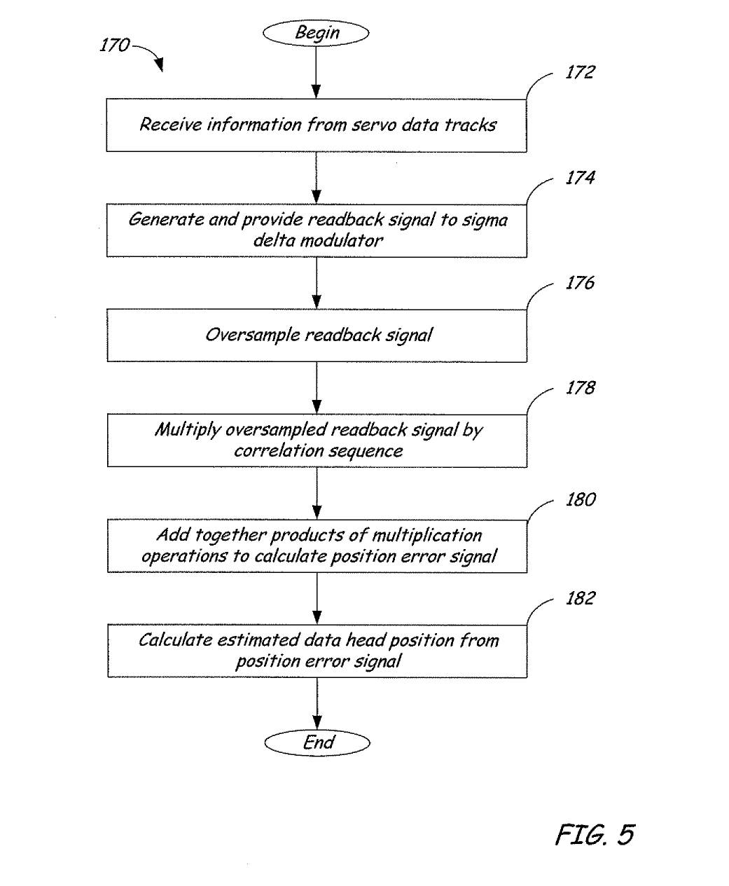

FIG. 5 illustrates a method 170 of handling information read from servo data tracks according to one aspect of the invention. The method 170 includes receiving information read from servo data tracks on a data storage device by a read channel as shown in block 172. The received information illustratively includes the cross-track head position and a servo bit sequence. After receiving the information described above, a readback signal is provided by the read channel to a sigma delta modulator, as shown in block 174. The sigma delta modulator then samples the readback signal at a sampling rate greater than the frequency of data being provided by the readback signal. This is illustrated in block 176. The oversampled signal from the sigma delta modulator is then multiplied by a correlation sequence as shown in block 178. The product of the multiplication events are then summed together as at block 180 to create a position error signal. An estimated position of the data head is then calculated from the position error signal, as shown at block 182.

The complexity of the servo demodulation systems 150 and 200 begins to differentiate after the SDM in each system as the complexity prior to the SDM is substantially the same. Thus, a difference in the complexity of each of the systems can be analyzed by comparing the decimation filter, multiplication and summation operations. The servo demodulation system 150 has a decimation filter with several hundred taps. The servo demodulation system 200 has no decimation filter and none the attendant complexity. The multiplication operation in the each of servo demodulation systems 150 and 200 can be realized with bit flipping operations. The two servo demodulation systems 150 and 200 perform multiplication at different rates, however. The servo demodulation system 150 performs multiplication at the baud rate fₛ while the servo demodulation system 200 performs multiplication at M times the baud rate fₛ. Likewise, the servo demodulation system 150 performs summation at the baud rate fₛ while the servo demodulation system 200 performs summation at M times the baud rate fₛ. While the servo demodulation system 200 provides more complexity in the multiplication and summation functions, the complexity savings by not having a decimation filter provides a large enough savings in complexity to overcome the aforementioned additional complexities given certain relevant parameters as will be described below. For the common activities between the servo demodulation systems 150 and 200 it is assumed that bit flipping and single bit addition have the same computational complexity. Thus, the measurement of the computational complexity of the two servo demodulation systems includes measuring the total number of required bit operations for each of bit flipping and single bit addition.

For the servo demodulation system 150, the complexity of the decimation filter must be calculated as well. The quantization noise in {y _{k̅}} lies within the high frequency region. To attenuate such quantization noise, the decimation filter 154 of the servo demodulation system 150 is chosen to be a low-pass filter. One example of a decimation filter for servo demodulation system 150 can be described as:

F(z)=(1+z⁻¹+ . . . +z^{-(M-1)})^{m}

where z⁻¹ is a one step delay at the oversampled rate and m is the order of the decimation filter. To efficiently attenuate the quantization noise in the high frequency region, the order of the decimation filter, m, cannot be too low—typical settings for m are from 3 to 5. The total computation complexity of the servo demodulation system 150 is dominated by the computation complexity of the decimation filter.

For the servo demodulation system 200, the summation

$${\sum }_{k} {d}_{\overline{k}}$$

(where d _{k̅}=c _{k̅}·z _{k̅}) is executed at the over sampled rate Mfₛ. The summation can be described in two separate steps, where:

$${\sum }_{k} {d}_{\overline{k}} = {\sum }_{k} {p}_{k}$$

and where:

$${p}_{k} = {\sum }_{\overline{k} = M ( k - 1 ) + 1}^{M \overline{k}} {d}_{\overline{k}} .$$

The summation in the first equation works at the baud rate fₛ, while the summation in the second equation works at the oversampled rate. The total complexity of the system 200 is primarily a function of bit flipping (c _{k̅}*y _{k̅}) and the summation illustrated in the second equation above. When the order of the decimation filter of servo demodulation system 150 m=3, and M is set to 16 or 32, servo demodulation system 200 provides non-trivial savings in computational complexity when B̅≦10. Furthermore, it has been found that the computational complexity has not been at the cost of performance as is shown below.

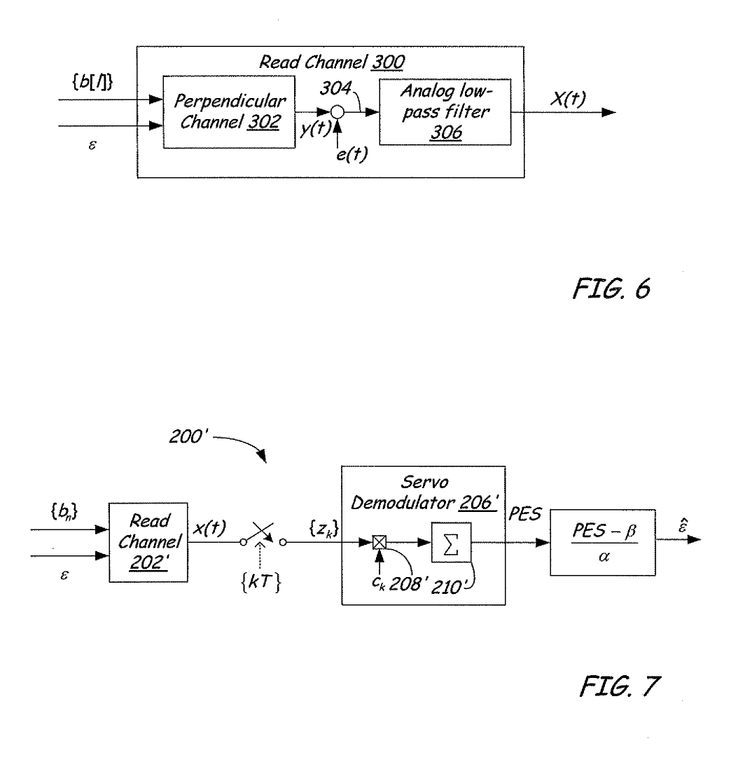

FIG. 6 illustrates a read channel 300 of the type used in servo demodulation system 200 in more detail. The read channel 300 includes a perpendicular magnetic channel 302 with a normalized density of 2.0 that receives as inputs the bit sequence {b[l]} and the cross-track position ε. The output y(t) of the perpendicular magnetic channel 302 is illustratively perturbed by electronics noise, e(t). The electronics noise e(t) is modeled as additive white Gaussian noise with zero mean and the single-sided power spectral density of N₀. To attenuate electronic noise e(t), the resultant signal 304 is illustratively passed through a low-pass filter 306 with a bandwidth of

$$\frac{1}{2 T} Hz , .$$

where T is the channel bit size. The signal to noise ratio of the system is defined as

$$SNR = 10 {log}_{10} \frac{1}{{N}_{0}} ( dB ) .$$

The servo demodulation system 200, as discussed above, includes a sigma-delta ADC 100, which introduces ADC error into the readback signal {zₖ}.

FIG. 7 illustrates a simulated servo demodulation system 200′, which is substantially similar to the servo demodulation system 150, with the exception that an ideal ADC is substituted for the sigma delta ADC 100 shown in servo demodulation system 150. The ideal ADC has infinite resolution, which is denoted in FIG. 7 by a direct connection between the read channel block 202′ and the baud rate sampler (sampling at a rate of T). Simulations have shown improved that is, lower, variance of the normalized estimation error (\hat{ε}−ε)/W_{track}, where W_{track} is the width of a particular servo data track. Thus, not only is complexity improved, but performance as well.

In summary, the illustrative embodiments can provide for the following advantages. By taking advantage of a sigma-delta ADC into the servo demodulation system, significant reductions in power consumption and complexity can be achieved, which provides improved servo demodulation performance under the given computational complexity. In addition, by providing an oversampled signal directly to the servo demodulator, the computational complexity is decreased by avoiding the complex decimation filter calculations. Furthermore, in relevant computational ranges, performance is increased, meaning that the normalized variance between the estimated cross track position and the actual cross track position is reduced, thereby providing improved position accuracy of the probe tips. Thus, the servo demodulation system for calculating cross track position estimations shown here in the above illustrative aspects are well suited for many data communication applications such as probe storage devices, which require high performance with low power requirements.

It is to be understood that even though numerous characteristics and advantages of the various embodiments have been set forth in the foregoing description, together with details of the structure and function of various embodiments, this disclosure is illustrative only, and changes may be made in detail, especially in matters of structure and arrangement of parts within the principles of the present embodiments to the full extent indicated by the broad general meaning of the terms in which the appended claims are expressed. For example, the particular elements may vary depending on the particular application for the servo demodulation system while maintaining substantially the same functionality without departing from the scope and spirit of the present embodiments. In addition, although the embodiments described herein is directed to data communication channel for a data storage system, it will be appreciated by those skilled in the art that the teachings of the present embodiments can be applied to other systems that use data communication channels, without departing from the scope and spirit of the present embodiments.

What is claimed is:

1. A method, comprising:
receiving an analog signal from a data channel;
converting the analog signal to a one bit wide digital signal at an oversampled frequency; and
calculating a position error signal by summing correlated oversampled digital signals.

2. The method of claim 1 and further comprising:
correlating the oversampled digital signals by multiplying the oversampled digital signals by a correlation sequence.

3. The method of claim 2 and further comprising:
providing a correlation sequence to be multiplied by the oversampled digital signals.

4. The method of claim 3, wherein providing a correlation sequence includes providing a signed fixed point number.

5. The method of claim 1, wherein converting the analog signal to a one bit wide digital signal is performed by a sigma delta modulator.

6. The method of claim 1 and further comprising:
calculating an estimated position of a data head relative to a data storage device from the position error signal.

7. The method of claim 1, wherein receiving the analog signal includes receiving an analog signal indicative of data on a servo data track.

8. The method of claim 7, wherein receiving the analog signal includes receiving an analog signal indicative of the position of a data head relative to the servo data track.

9. The method of claim 8 and further comprising:
providing a readback signal to be converted to a digital signal including indications of the position of the data head relative to the servo data track.

10. A system, comprising:
a data channel configured to read an analog signal;
a sigma delta modulator in communication with the data channel and configured to convert the analog signal to a digital signal at an oversampled rate; and
a servo demodulator in communication with the sigma delta modulator for calculating a position error signal from the oversampled digital signal.

11. The system of claim 10, wherein the servo demodulator includes a multiplier in communication with the sigma delta modulator.

12. The system of claim 11, wherein the multiplier is configured to multiply the digital signal with a low resolution correlation coefficient.

13. The system of claim 11, wherein the servo demodulator is configured to provide a correlation sequence to be multiplied with output from the sigma delta modulator.

14. The system of claim 11, wherein the servo demodulator includes an adder in communication with the multiplier and wherein the adder adds a plurality of products from the multiplier together.

15. The system of claim 10, wherein the oversampled rate is an integer multiple of a baud rate of the analog signal.

16. A method, comprising:
converting an analog signal to a one bit wide digital signal by sampling the analog signal at an oversampled frequency;
calculating a position error signal by summing a plurality of digital signals at the oversampled frequency; and
determining an estimated data head position based on the position error signal.

17. The method of claim 16 and further comprising:
correlating the one bit wide digital signal by multiplying samples of the digital signal by a correlation sequence.

18. The method of claim 17, wherein calculating the position error signal includes summing previously correlated sampled of the digital signal.

19. The method of claim 16, wherein converting the analog signal includes converting an analog signal indicative of data on a servo data track.

20. The method of claim 16, wherein converting the analog signal includes converting an analog signal indicative of the position of a data head relative to a servo data track.
